(19) United States
(12) Patent Application Publication
(10) Pub. No.: US 2011/0233680 A1
(43) Pub. Date: Sep. 29, 2011

(54) NONVOLATILE MEMORY DEVICE AND METHOD FOR MANUFACTURING SAME

(75) Inventors: Saku HASHIURA, Mie-ken (JP); Shinichi WATANABE, Kanagawa-ken (JP); Takeshi SHIMANE, Chiba-ken (JP); Norihisa ARAI, Saitama-ken (JP)

(73) Assignee: Kabushiki Kaisha Toshiba, Tokyo (JP)

(21) Appl. No.: 12/886,007

(22) Filed: Sep. 20, 2010

(30) Foreign Application Priority Data
Mar. 25, 2010 (JP) 2010-071122

(51) Int. Cl. H01L 27/088; H01L 21/336

(52) U.S. Cl. 257/368; 438/197; 257/E27.06; 257/E21.409

(57) ABSTRACT

According to one embodiment, a nonvolatile memory device including MOS transistors formed in a surface of one semiconductor substrate is provided. The device includes a first and second MOS transistors. The first MOS transistor includes a first source and drain regions spaced from each other, a first gate insulating film provided on the surface, a first gate electrode provided on the first gate insulating film, and a first channel region located immediately below the first gate insulating film and containing impurities of both conductivity types. The second MOS transistor includes a second source and drain regions spaced from each other, a second gate insulating film provided on the surface, a second gate electrode provided on the second gate insulating film, and a second channel region located immediately below the second gate insulating film and having an identical concentration profile of the impurity to the first channel region.

### CROSS-REFERENCE TO RELATED APPLICATIONS

This application is based upon and claims the benefit of priority from the prior Japanese Patent Application No. 2010-071122, filed on Mar. 25, 2010; the entire contents of which are incorporated herein by reference.

### FIELD

Embodiments described herein relate generally to a nonvolatile memory device and a method for manufacturing the same.

### BACKGROUND

The nonvolatile memory device is an LSI (large scale integration circuit) in which memory cells for storing information are integrated with various other peripheral circuits. For instance, a NAND flash memory is provided with driving circuits such as row decoders and sense amplifiers, and these circuits include a plurality of kinds of transistors with different threshold voltages.

Hence, in the process for manufacturing a nonvolatile memory device, a process is adapted to each of the plurality of kinds of transistors with different threshold voltages.

JP-A-2006-310602 discloses, in a process for manufacturing transistors with different threshold voltages having channels of the same conductivity type, a technique for shortening the process by integrating together the ion implantation processes.

### BRIEF DESCRIPTION OF THE DRAWINGS

FIG. 1 is a sectional view schematically showing the structure of a nonvolatile memory device according to one embodiment;

FIGS. 2A and 2B are schematic diagrams showing impurity profiles of the channel region of the MOSFET in the nonvolatile memory device according to one embodiment;

FIG. 3 is a schematic diagram showing an impurity profile of the channel region of the MOSFET in the nonvolatile memory device according to a variation of one embodiment;

FIGS. 4A to 6B are sectional views schematically showing a process for manufacturing the nonvolatile memory device according to one embodiment; and

FIGS. 7A to 7C are sectional views schematically showing the structure of nonvolatile memory devices according to a variation of one embodiment.

### DETAILED DESCRIPTION

In general, according to one embodiment, a nonvolatile memory device including a plurality of kinds of MOS transistors formed in a surface of one semiconductor substrate is provided. The device includes a first MOS transistor and a second MOS transistor. The first MOS transistor includes a first source region of a first conductivity type and a first drain region of the first conductivity type spaced from each other in the surface of the semiconductor substrate, a first gate insulating film provided on the surface of the semiconductor substrate between the first source region and the first drain region, a first gate electrode provided on the first gate insulating film, and a first channel region located immediately below the first gate insulating film between the first source region and the first drain region and containing both impurity of the first conductivity type and impurity of a second conductivity type. The second MOS transistor includes a second source region of the first conductivity type and a second drain region of the first conductivity type spaced from each other in the surface of the semiconductor substrate, a second gate insulating film provided on the surface of the semiconductor substrate between the second source region and the second drain region, a second gate electrode provided on the second gate insulating film, and a second channel region located immediately below the second gate insulating film between the second source region and the second drain region and having an identical concentration profile of the impurity of the first conductivity type to the first channel region.

According to another embodiment, a method for manufacturing a nonvolatile memory device including a plurality of kinds of MOS transistors formed in a surface of one semiconductor substrate is disclosed. The method includes ion-implanting impurity of a second conductivity type into a region constituting a channel of a first MOS transistor, simultaneously ion-implanting impurity of a first conductivity type into the region constituting the channel of the second MOS transistor and the region constituting the channel of the first MOS transistor, and ion-implanting the impurity of the first conductivity type into the region constituting the channel of the third MOS transistor simultaneously with the regions constituting the channel of the first MOS transistor and the second MOS transistor. The ion-implanting impurity of the second conductivity type is performed by masking a region constituting a channel of a third MOS transistor, which includes a gate insulating film thicker than gate insulating films of the first MOS transistor and a second MOS transistor formed in the semiconductor substrate, and a region constituting a channel of the second MOS transistor.

An embodiment of the invention will now be described with reference to the drawings. In the following embodiment, like portions in the figures are labeled with like reference numerals, the detailed description thereof is omitted as appropriate, and the different portions are described as appropriate. Although the following description assumes that the first conductivity type is n-type and the second conductivity type is p-type, the first conductivity type can be p-type and the second conductivity type can be n-type.

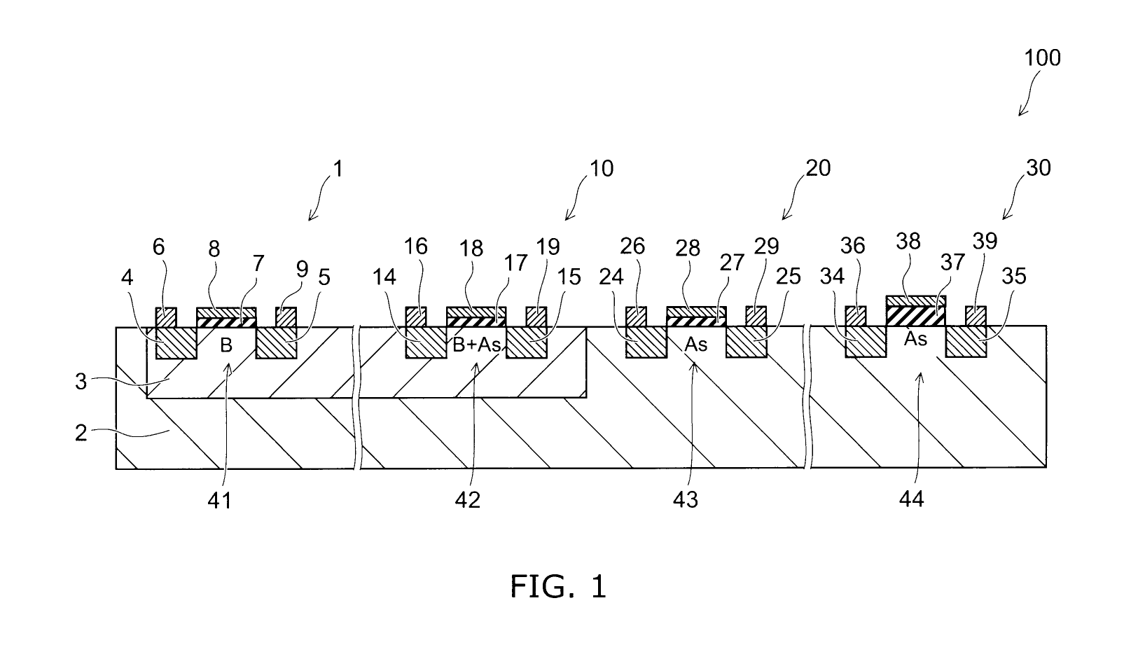

FIG. 1 is a sectional view schematically showing the structure of a nonvolatile memory device 100 according to one embodiment. As shown in this figure, the nonvolatile memory device 100 according to this embodiment includes a MOSFET 1, MOSFET 10, MOSFET 20, and MOSFET 30, which are a plurality of kinds of MOS transistors, on one semiconductor substrate 2. In the following, unless otherwise specified, the “channel region” refers to a region located below the gate electrode and sandwiched between the source and drain region.

The semiconductor substrate 2 is illustratively a silicon substrate having p-type conductivity, and includes a p-type well 3 doped with p-type impurity at higher concentration than the semiconductor substrate 2 in an upper portion of the semiconductor substrate 2. Because the “surface of the well” is equivalent to the “surface of the semiconductor substrate”, in the following, the “surface of the well” may be termed as the “surface of the semiconductor substrate”.

For instance, the MOSFET 1 and the MOSFET 10 provided in the p-type well are enhancement type (E-type) n-channel transistors, and the threshold voltage of the MOSFET 10 is lower than the threshold voltage of the MOSFET 1. The MOSFET 20 provided in the p-type semiconductor substrate 2 is a depression type (D-type) n-channel transistor. Likewise, the MOSFET 30 provided in the p-type semiconductor substrate 2 is a D-type n-channel transistor.

Furthermore, the MOSFET 30 is a transistor having higher breakdown voltage than the MOSFET 1, MOSFET 10, and MOSFET 20. Specifically, for instance, the gate insulating film 37 can be made thicker than that of the other MOSFETs to increase the gate-drain and gate-source breakdown voltage. Alternatively, besides the MOSFET 30, the high breakdown voltage n-channel transistor may be of the E-type, the D-type, or the intrinsic type (I-type) having a threshold between the E-type and the D-type.

As shown in FIG. 1, the MOSFET 1 includes an n-type source region 4 and drain region 5 spaced from each other in the surface of the p-type well 3, and includes a gate electrode 8 via a gate insulating film 7 provided on the surface of the p-type well 3 between the source region 4 and the drain region 5. The channel region 41 between the source region 4 and the drain region 5 is doped with boron (B) as p-type impurity.

A contact 6 and a contact 9 are electrically connected to the source region 4 and the drain region 5, respectively.

The MOSFET 10 as a first MOS transistor includes a source region 14 as an n-type first source region, and a drain region 15 as an n-type first drain region, spaced from each other in the surface of the p-type well 3. A gate insulating film 17 as a first gate insulating film is provided on the surface of the p-type well 3 between the source region 14 and the drain region 15, and a gate electrode 18 as a first gate electrode is provided on the gate insulating film 17.

The channel region 42 as a first channel region sandwiched between the source region 14 and the drain region 15 and located immediately below the gate insulating film 17 contains both n-type impurity and p-type impurity. For instance, the channel region 42 of the MOSFET 10 shown in FIG. 1 contains B as p-type impurity and arsenic (As) as n-type impurity.

A contact 16 and a contact 19 are electrically connected to the source region 14 and the drain region 15, respectively.

The MOSFET 20 as a second MOS transistor includes a source region 24 as an n-type second source region, and a drain region 25 as an n-type second drain region, spaced from each other in the surface of the semiconductor substrate 2. A gate insulating film 27 as a second gate insulating film is provided on the surface of the semiconductor substrate 2 between the source region 24 and the drain region 25, and a gate electrode 28 as a second gate electrode is provided on the gate insulating film 27.

The channel region 43 as a second channel region sandwiched between the source region 24 and the drain region 25 and located immediately below the gate insulating film 27 contains n-type impurity having nearly the same concentration profile as the channel region 42 of the MOSFET 10. Here, “nearly the same” means including manufacturing variation. Specifically, the channel region 43 of the MOSFET 20 contains As as n-type impurity, and the concentration profile of As is nearly the same as that of the channel region 42.

A contact 26 and a contact 29 are electrically connected to the source region 24 and the drain region 25, respectively.

The MOSFET 30 as a third MOS transistor includes a source region 34 as an n-type third source region, and a drain region 35 as an n-type third drain region, spaced from each other in the surface of the semiconductor substrate 2. A gate insulating film 37 as a third gate insulating film is provided on the surface of the semiconductor substrate 2 between the source region 34 and the drain region 35, and a gate electrode 38 as a third gate electrode is provided on the gate insulating film 37.

The channel region 44 as a third channel region sandwiched between the source region 34 and the drain region 35 and located immediately below the gate insulating film 37 contains n-type impurity having nearly the same concentration profile as the channel region 42 of the MOSFET 10 and the channel region 43 of the MOSFET 20. Specifically, as shown in FIG. 1, the channel region 44 contains As as n-type impurity, and the concentration profile of As is nearly the same as As contained in the channel regions 42 and 43. In this specification, the “depth direction” refers to the depth in the direction from the front surface of the semiconductor substrate 2 with the MOSFET 1 and the like formed therein, toward the rear surface opposite to the front surface of the semiconductor substrate 2.

A contact 36 and a contact 39 are electrically connected to the source region 34 and the drain region 35, respectively.

Furthermore, the channel region 44 of the MOSFET 30 can be doped with p-type impurity in addition to n-type impurity. An E-type or I-type n-channel transistor with high breakdown voltage can be formed by varying the doping amount of n-type impurity and p-type impurity doped in the channel region 44 of the MOSFET 30.

As described above, the nonvolatile memory device 100 according to this embodiment can include a plurality of kinds of MOS transistors with different threshold voltages by varying the type and doping amount of impurity doped in each of the channel regions 41-44 of the MOSFETs 1, 10, 20, and 30. Furthermore, impurity constituting a channel region may be provided also between the MOSFET 1, MOSFET 10, MOSFET 20, and MOSFET 30 (in the surface of the semiconductor substrate 2 between the source/drain regions of the MOSFETs).

As described later, in the process for manufacturing the nonvolatile memory device 100, n-type impurity doped in the channel region 42 of the MOSFET 10, the channel region 43 of the MOSFET 20, and the channel region 44 of the MOSFET 30 is simultaneously ion-implanted. Hence, the concentration profiles of n-type impurity doped in the channel regions 42 to 44 are nearly the same.

The channel region 42 of the MOSFET 10 formed in the p-type well 3 is doped with As as n-type impurity, in addition to B as p-type impurity, by using ion implantation. Furthermore, the implantation amount (dose amount) of B is made larger than the dose amount of As so that the channel region 42 is formed to be of p-type.

As described later with reference to the manufacturing process, B doped in the channel region 41 of the MOSFET 1 and B doped in the channel region 42 of the MOSFET 10 are simultaneously ion-implanted. Hence, the dose amounts of B ion-implanted into the channel region 41 and the channel region 42 are nearly the same. In the channel region 42, part of p-type impurity (B) is compensated by n-type impurity (As), and hence the p-type carrier concentration is lower than in the channel region 41. Thus, the threshold voltage of the MOSFET 10 including the channel region 42 is lower than the threshold voltage of the MOSFET 1 including the channel region 41. Hence, two kinds of E-type MOSFETs with different threshold voltages are formed in the surface of the p-type well 3.

On the other hand, the channel region 43 of the MOSFET 20 formed directly on the p-type semiconductor substrate 2 has n-type conductivity because n-type impurity (As) is ion-implanted therein. Hence, the MOSFET 20 is formed as a D-type n-channel transistor having a negative threshold voltage.

As described above, in the process for manufacturing the nonvolatile memory device 100 according to this embodiment, p-type impurity is simultaneously ion-implanted into the channel region 41 of the MOSFET 1 and the channel region 42 of the MOSFET 10 which are provided in the p-type well 3. Furthermore, n-type impurity is simultaneously ion-implanted into the channel region 42 of the MOSFET 10 and into the channel region 43 of the MOSFET 20 which is provided directly on the p-type semiconductor substrate 2.

Thus, by two times of ion implantation, two kinds of E-type MOSFETs 1 and 10 and a D-type MOSFET 20 having different threshold voltages can be provided. As compared with the method of providing three kinds of MOSFETs by separate ion implantation into each channel region, the number of times of ion implantation can be reduced by one. This makes it possible to reduce TAT (turn around time) and cost. Furthermore, as described later, in the MOSFET 10 containing both p-type impurity and n-type impurity in the channel region 42, the controllability of the threshold voltage can be improved.

The MOSFET 10 has a lower threshold voltage than the MOSFET 1, and hence the response speed is accelerated. Thus, the MOSFET 10 can be used for a circuit in which a transistor with fast response speed is to be placed. For instance, it is advantageously used in an input/output buffer circuit, whose response speed tends to slow down because a wide diffusion layer is provided near the input pad.

The n-type impurity ion-implanted into the channel regions 42-44 of the MOSFETs 10, 20, and 30 can be one of nitrogen (N), phosphorus (P), and antimony (Sb) instead of As described above. Use of N and P having lower atomic weight than As can reduce damage at the time of ion implantation, and hence the breakdown voltage of the pn junction can be increased. Thus, for instance, it is advantageous in increasing the breakdown voltage of a high breakdown voltage device such as the MOSFET 30.

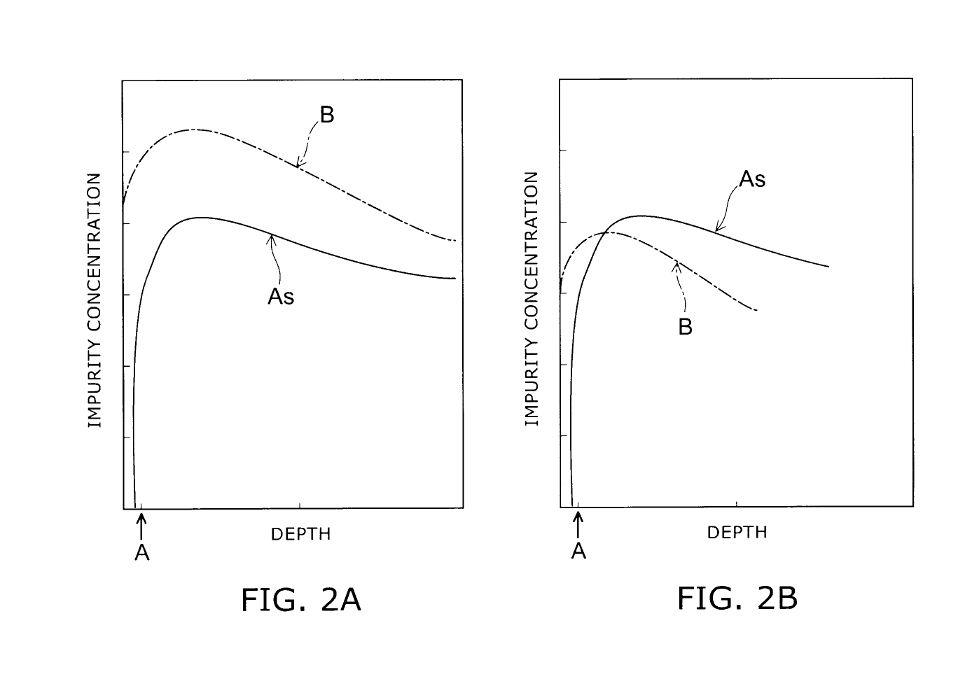

FIGS. 2A and 2B are schematic diagrams showing impurity profiles of the channel region of the MOSFET in the nonvolatile memory device 100 according to one embodiment. FIG. 2A is a schematic diagram showing the concentration profile of p-type impurity (B) and n-type impurity (As) doped in the channel region 42 of the MOSFET 10. FIG. 2B is a schematic diagram showing the concentration profile of p-type impurity (B) and n-type impurity (As) doped in the channel region 44 of the MOSFET 30. In each figure, the vertical axis represents impurity concentration on a logarithmic scale, and the horizontal axis represents depth from the surface. Here, the impurity profiles shown in FIGS. 2A and 2B are calculated by using an in-house simulator. The result is calculated under the condition of implanting each impurity from the protective insulating film. The reference point of depth on the horizontal axis (the intersection between the vertical axis and the horizontal axis) is the upper surface of the protective insulating film, and the surface of the semiconductor substrate 2 is located at position A. Furthermore, the bottom surface of the source region and the drain region is located nearly at the center of the horizontal axis.

As shown in FIG. 2A, in the depth direction, the peak value of the concentration profile of p-type impurity (B) in the channel region 42 of the MOSFET 10 is higher than the peak value of the concentration profile of n-type impurity (As). Furthermore, the peak position of the concentration profile of B and the peak position of the concentration profile of As are located at nearly the same depth. Entirely in the depth direction from the surface, n-type impurity (As) compensates p-type impurity (B) and reduces the concentration of p-type carriers in the channel region 42.

Thus, by matching the peak positions of p-type impurity and n-type impurity, p-type impurity can be efficiently compensated by a small dose amount of n-type impurity. Furthermore, the controllability of the p-type carrier concentration in the channel region 42 can be improved.

On the other hand, the channel region 43 of the MOSFET 20, in which the implantation amount of B is smaller than in FIG. 2A, is doped with As. The concentration profile of As ion-implanted into the channel region 43 is nearly the same as the concentration profile of As shown in FIG. 2A. Furthermore, the p-type impurity concentration of the p-type semiconductor substrate 2 is partly lower than the concentration profile of As. Hence, in the MOSFET 20, the conductivity type of the channel region 43 near the gate insulating film 27 is effectively n-type. Furthermore, in the case where the gate insulating film is formed by thermal oxidation, the upper surface of the channel region 43 is altered into an oxide film. Hence, the concentration of As in the upper surface of the channel region 43 may be higher than the concentration of B and cause the conductivity type of the channel region 43 to be n-type.

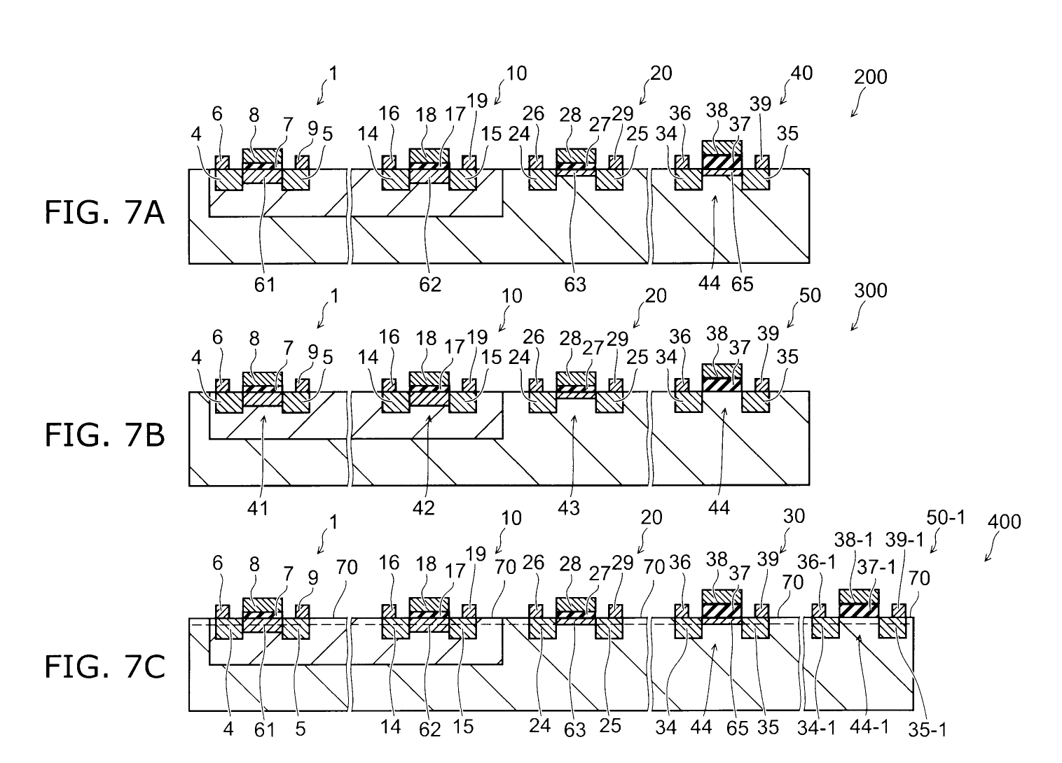

As shown in FIG. 2B, in this embodiment, the channel region 44 of the MOSFET 30 contains p-type impurity (B) and n-type impurity (As). The n-type impurity (As) is ion-implanted simultaneously with the channel region 42 of the MOSFET 10 and the channel region 43 of the MOSFET 20, and has nearly the same concentration profile is as As shown in FIG. 2A. Furthermore, p-type impurity (B) shown in FIG. 2B is p-type impurity used in the channel region 44-1 (p-type region 70) of the MOSFET 50-1 in FIG. 7C described later.

On the other hand, B implanted into the channel region 41 of the MOSFET 1 and the channel region 42 of the MOSFET 10 is ion-implanted by a separate process in addition to p-type impurity (B) shown in FIG. 2B. Hence, the concentration profile of B shown in FIG. 2A can illustratively have a higher peak concentration and a deeper peak position than the concentration profile of B shown in FIG. 2B.

In the channel region 44 having the concentration profile of p-type impurity and n-type impurity shown in FIG. 2B, B is additionally ion-implanted in a separate process. Alternatively, by omitting implantation of As, n-channel transistors can be formed separately to be of E-type, I-type, and D-type.

For instance, if As is not implanted and the implantation amount of B is increased, then the threshold voltage increases, and an E-type n-channel transistor is formed. Furthermore, for instance, if As is not implanted, then an I-type n-channel transistor is formed with the impurity concentration of B being nearly the same as, or slightly higher than, the impurity concentration of the semiconductor substrate 2. On the other hand, by adjusting the dose amount of B, the threshold of the E-type and I-type n-channel transistor can also be adjusted.

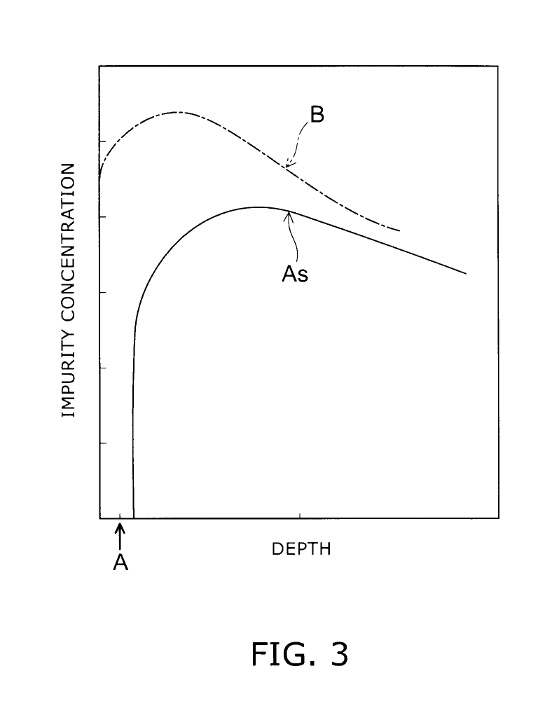

FIG. 3 is a schematic diagram showing an impurity profile of the channel region 42 of the MOSFET 10 in the nonvolatile memory device according to a variation of this embodiment. The vertical axis represents impurity concentration on a logarithmic scale, and the horizontal axis represents depth from the surface. Furthermore, p-type impurity (B) shown in FIG. 3 has the same profile with the p-type impurity (B) shown in FIG. 2A.

In the example shown in FIG. 3, the peak position of the concentration profile of n-type impurity (As) is deeper than the peak position of the concentration profile of p-type impurity (B). Because the peak concentration of B is higher than the peak concentration of As, as in the embodiment shown in FIG. 2A, the MOSFET 10 is an E-type n-channel transistor with the channel region 42 having p-type conductivity. Such a concentration profile can be realized by increasing the acceleration energy for ion implantation of As, or by decreasing the acceleration energy for ion implantation of B.

The peak position (ion implantation depth) of the distribution of ion-implanted impurity atoms in the depth direction depends on the acceleration energy, and nearly coincides with the peak position of the concentration profile of impurity activated by heat treatment.

In the concentration profile of B and As shown in FIG. 3, n-type impurity (As) compensates p-type impurity (B) at positions deeper than the peak position of the concentration profile of B. Hence, the tail portion in the depth direction of the concentration profile of B is compensated by As, and the concentration becomes even lower. This results in a distribution without tail in which p-type carriers are confined on the surface side (gate insulating film 17 side), and the controllability of the threshold voltage can be improved.

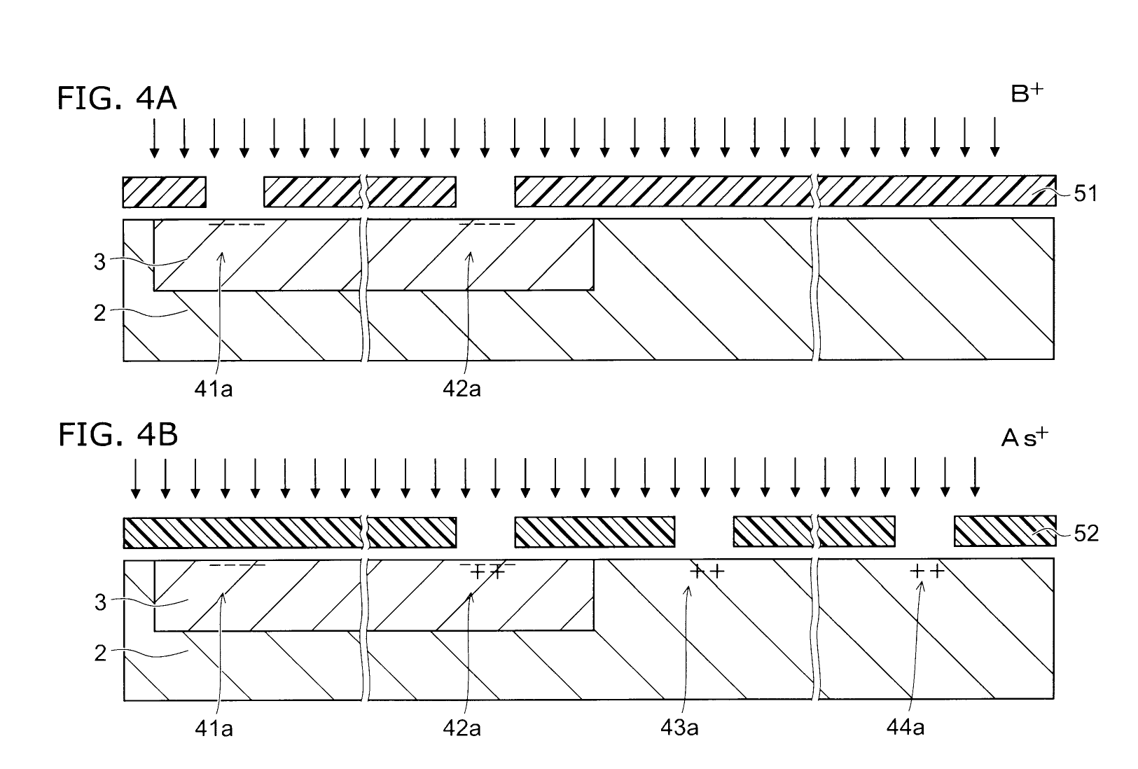

FIGS. 4A to 6B are sectional views schematically showing a process for manufacturing the nonvolatile memory device 100 according to one embodiment.

The method for manufacturing the nonvolatile memory device 100 according to this embodiment is a manufacturing method by which a plurality of kinds of MOSFETs are provided in the surface of one semiconductor substrate 2, and includes the process of ion-implanting p-type impurity into a region 42a constituting a channel of a MOSFET 10 provided in the semiconductor substrate 2, and the process of simultaneously ion-implanting n-type impurity into a region 43a constituting a channel of a MOSFET 20 and the region 42a constituting the channel of the MOSFET 10 provided in the semiconductor substrate 2.

Furthermore, n-type impurity is ion-implanted into a region 44a constituting a channel of a MOSFET 30 provided in the semiconductor substrate 2 and having higher breakdown voltage than the MOSFET 10 and the MOSFET 20 simultaneously with the regions 42a, 43a constituting the channel of the MOSFET 10 and the MOSFET 20.

FIG. 4A is a sectional view showing the process of ion-implanting B as p-type impurity into the semiconductor substrate 2. The semiconductor substrate 2 is illustratively a silicon substrate low doped with p-type impurity, and a p-type well 3 having higher impurity concentration than the semiconductor substrate 2 is provided in an upper portion of the semiconductor substrate 2.

An implantation mask 51 with openings corresponding to a region 41a constituting a channel of a MOSFET 1 and the region 42a constituting the channel of the MOSFET 10 is used to ion-implant p-type impurity (B) into the surface of the p-type well 3. The implantation energy and the dose amount of B are conditioned so that the threshold voltage of the MOSFET 1 has a predetermined value. At this time, the regions 43a, 44a constituting the channel of the MOSFET 20 and the MOSFET 30 are covered with the mask 51.

As shown in FIG. 4B, an implantation mask 52 with openings corresponding to the region 42a constituting the channel of the MOSFET 10, the region 43a constituting the channel of the MOSFET 20, and the region 44a constituting the channel of the MOSFET 30 is used to ion-implant n-type impurity (As) into the surface of the p-type well 3 and the semiconductor substrate 2. At this time, the region 41a constituting the channel of the MOSFET 1 is covered with the mask 52.

The implantation energy and the dose amount of As are conditioned so that As compensates B previously implanted into the region 42a and the threshold voltage of the MOSFET 10 has a predetermined value. Furthermore, the dose amount of As is such that an n-type impurity region is formed near the surface of the region 43a constituting the channel of the MOSFET 20.

As shown in FIG. 2A, the implantation energy may be set so that the peak position of the concentration profile of B coincides with the peak position of the concentration profile of As. Alternatively, as shown in FIG. 3, the implantation energy can be set higher so that the peak position of the concentration profile of As is deeper than the peak position of the concentration profile of B.

Furthermore, instead of As, one of nitrogen (N), phosphorus (P), and antimony (Sb) can be ion-implanted. In the nonvolatile memory device 100 according to this embodiment, the dose amount of p-type impurity (B) is larger than the dose amount of n-type impurity so that the MOSFET 1 and the MOSFET 10 provided in the p-type well are formed as E-type n-channel transistors.

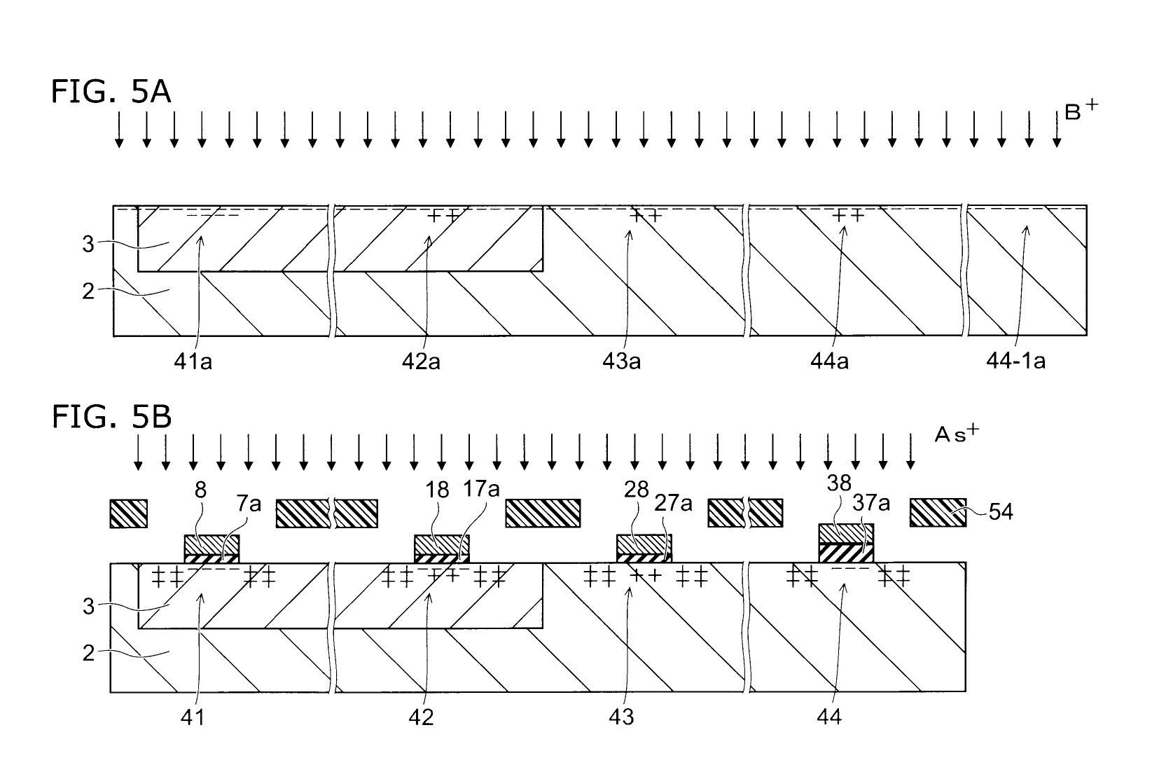

In the case where the MOSFET 30 is of E-type, B is ion-implanted in a dose amount such that the surface neighborhood of the region 44a is of p-type and exhibits a predetermined threshold voltage. Furthermore, in the case of manufacturing a nonvolatile memory device 400 described later with reference to FIG. 7C, p-type impurity (B) is ion-implanted into the entire surface of the semiconductor substrate 2 as shown in FIG. 5A. The dose amount is adjusted so that the impurity concentration of this p-type region 70 doped with p-type impurity (B) is slightly higher than the p-type impurity concentration of the semiconductor substrate 2.

As illustrated in this embodiment, after n-type impurity is simultaneously ion-implanted into the region 42a constituting the channel of the MOSFET 10, the region 43a constituting the channel of the MOSFET 20, and the region 44a constituting the channel of the MOSFET 30, p-type impurity doped in the region 44a may be ion-implanted. Alternatively, simultaneously with the region 42a and the region 43a, n-type impurity may be ion-implanted into the region 44a containing p-type impurity previously ion-implanted in a separate process.

As shown in FIG. 5B, a gate insulating film and a gate electrode of the MOSFET 1, MOSFET 10, MOSFET 20, and MOSFET 30 are formed. The insulating film 37a constituting the gate insulating film 37 of the MOSFET 30 is formed thicker than the other insulating films 7a, 17a, and 27a to increase the gate-drain breakdown voltage.

An implantation mask 54 with openings corresponding to the regions where the MOSFET 1, MOSFET 10, MOSFET 20, and MOSFET 30 are to be provided, and the gate electrodes are used as a mask to ion-implant As, for instance, as n-type impurity into portions constituting source regions and drain regions. Here, P can be used instead of As. At this time, p-type MOSFETs are covered with the mask 54.

As shown in FIG. 5B, insulating films 7a, 17a, 27a, and 37a constituting gate insulating films, and gate electrodes 8, 18, 28, and 38 are provided, respectively, in the regions where the MOSFET 1, MOSFET 10, MOSFET 20, and MOSFET 30 are to be provided. Here, in the case where the insulating films 7a, 17a, 27a, and 37a are formed by thermal oxidation, the surface position of the semiconductor substrate 2 may vary. In this case, the surface portion of the channel region 44 becomes an oxide film. Thus, in the depth direction of the channel region with reference to the position of the surface of the semiconductor substrate 2, the As profile in the channel region 44 becomes different from that in the channel regions 42 and 43.

Thus, in the case where the insulating films 7a, 17a, 27a, and 37a are formed by thermal oxidation (in the case where the surface position of the semiconductor substrate 2 in the channel region 44 is different from that in the channel regions 42 and 43), the concentration profile of As in the channel regions 42 and 43 being the same as that in the channel region 44 means that the concentration profiles of As in the depth direction are nearly the same in consideration of the case where the upper surface of the respective channel regions becomes a gate insulating film.

In the openings provided in the mask 54, n-type impurity As is implanted into the surface of the semiconductor substrate 2. On the other hand, in the portion where the gate electrodes 8, 18, 28, and 38 are provided, each gate electrode functions as an implantation mask, and channel regions 41-44 are formed below the gate electrodes 8, 18, 28, and 38.

By heat treatment of the semiconductor substrate 2, ion-implanted n-type impurity and p-type impurity are activated by application of heat, for instance, to form the source region, drain region, and channel region of each MOSFET.

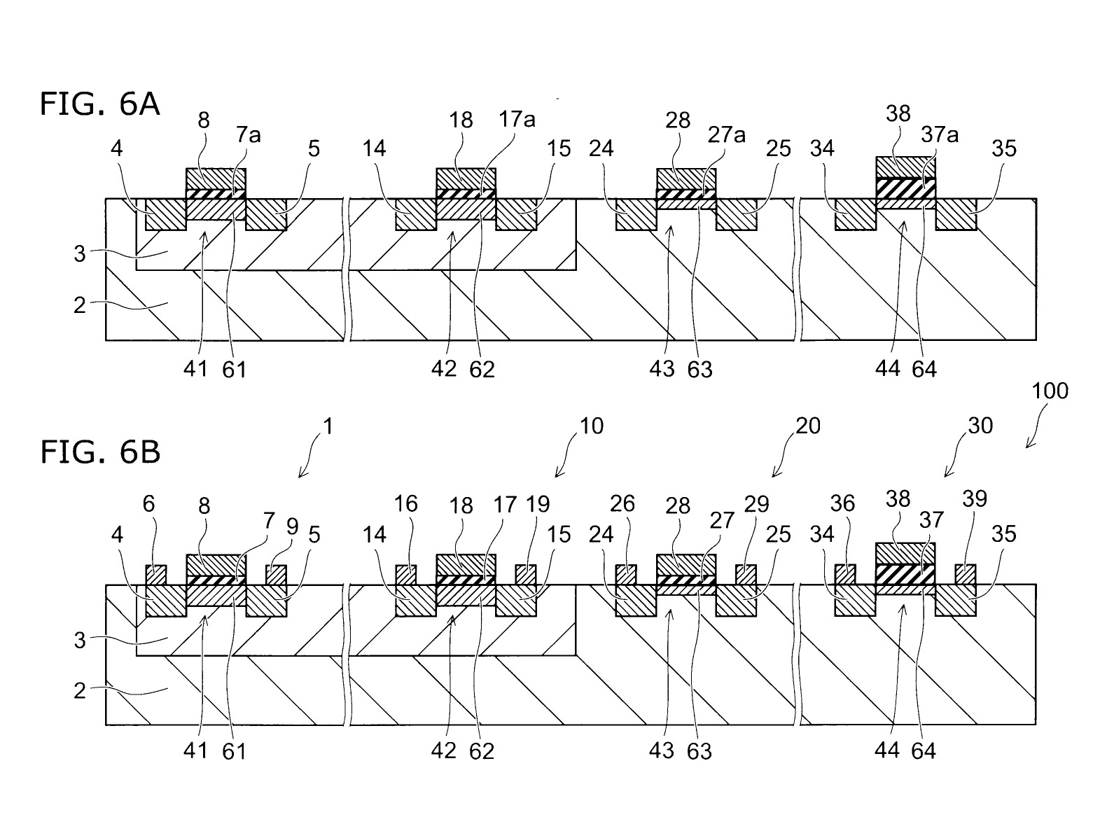

As shown in FIG. 6A, in the channel region 41 formed between the source region 4 and the drain region 5, a p-type region 61 containing B is formed near the insulating film 7a constituting the gate insulating film 7. In the channel region 42 formed between the source region 14 and the drain region 15, a p-type region 62 containing B and As is formed near the insulating film 17a constituting the gate insulating film 17. On the other hand, in the channel region 43 formed between the source region 24 and the drain region 25, an n-type region 63 containing As is formed near the insulating film 27a constituting the gate insulating film 27. Furthermore, in the channel region 44 formed between the source region 34 and the drain region 35, a p-type region 64 containing As is illustratively formed near the insulating film 37a constituting the gate insulating film 37.

As shown in FIG. 6B, contacts 6,9,16,19,26,29,36 and 39 electrically connected to the source region and the drain region, respectively, are provided, completing a MOSFET 1, MOSFET 10, MOSFET 20, and MOSFET 30.

In the nonvolatile memory device 100 manufactured by the above manufacturing method, the MOSFET 1, which is an E-type n-channel transistor, and the MOSFET 10, which is an E-type n-channel transistor having a lower threshold voltage than the MOSFET 1, are provided in the p-type well of the semiconductor substrate 2. Furthermore, the MOSFET 20, which is a D-type n-channel transistor, and the MOSFET 30 with high breakdown voltage, which is an E-type n-channel transistor, are provided directly in the p-type semiconductor substrate 2.

FIGS. 7A to 7C are sectional views schematically showing the structure of nonvolatile memory devices according to a variation of one embodiment. In the nonvolatile memory devices 200 and 300 according to this variation, the configuration of the MOSFET 1, MOSFET 10, and MOSFET 20 provided in the surface of the semiconductor substrate 2 is the same as that in the nonvolatile memory device 100. On the other hand, the configuration of the channel region 44 of the MOSFET 30 is different from that in the nonvolatile memory device 100.

In the nonvolatile memory device 200 shown in FIG. 7A, the MOSFET 40 is an E-type n-channel transistor, in which a p-type region 65 is formed near the gate insulating film 37 of the channel region 44. The p-type region 65 can be provided by omitting the process of ion-implanting n-type impurity into the channel region 44. Alternatively, it is also possible to increase the dose amount of ion-implanted p-type impurity.

In the nonvolatile memory device 300 shown in FIG. 7B, the MOSFET 50 is an I-type n-channel transistor, in which the neighborhood of the gate insulating film 37 of the channel region 44 is a p-type region with low concentration. The MOSFET 50 can be formed by omitting the process of ion-implanting n-type impurity and p-type impurity into the channel region 44.

Furthermore, as shown in FIG. 7C, it is also possible to form a p-type region 70 in the entire surface of the semiconductor substrate 2. The impurity concentration of this p-type region is low, at a level of slightly higher than the impurity concentration of the semiconductor substrate 2. This p-type region 70 is used as a channel region to form a MOSFET 50-1, which is an I-type n-channel transistor.

The MOSFET 50-1 includes a source region 34-1 as an n-type third source region and a drain region 35-1 as an n-type third drain region, spaced from each other in the surface of the semiconductor substrate 2. A gate insulating film 37-1 as a third gate insulating film is provided on the surface of the semiconductor substrate 2 between the source region 34-1 and the drain region 35-1, and a gate electrode 38-1 as a third gate electrode is provided on the gate insulating film 37-1. The channel region 44-1 does not contain As as n-type impurity, and is formed from the p-type region 70 formed in the entire surface of the semiconductor substrate 2.

On the other hand, the p-type region 70 is formed also in the surface of the MOSFET 1, MOSFET 10, MOSFET 20, and MOSFET 30. However, the impurity concentration thereof is low, and scarcely exerts an electrical effect on, for instance, the source region, which is an n-type diffusion layer.

Furthermore, the p-type region 70 is formed near the surface of the channel region 44 of the MOSFET 30. Also in this case, as shown in FIGS. 2B and 3, the MOSFET 30 can be formed as a D-type transistor by adjusting the amount of As implanted into the channel region 44.

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the devices and methods described herein may be made without departing from the spirit of the inventions. The accompanying claims and their equivalents are intended to cover such forms or modifications as would fall within the scope and spirit of the invention..

1. A nonvolatile memory device including a plurality of kinds of MOS transistors formed in a surface of one semiconductor substrate, the device comprising:
a first MOS transistor including:
a first source region of a first conductivity type and a first drain region of the first conductivity type spaced from each other in the surface of the semiconductor substrate;
a first gate insulating film provided on the surface of the semiconductor substrate between the first source region and the first drain region;
a first gate electrode provided on the first gate insulating film; and
a first channel region located immediately below the first gate insulating film between the first source region and the first drain region and containing both impurity of the first conductivity type and impurity of a second conductivity type; and
a second MOS transistor including:
a second source region of the first conductivity type and a second drain region of the first conductivity type spaced from each other in the surface of the semiconductor substrate;
a second gate insulating film provided on the surface of the semiconductor substrate between the second source region and the second drain region;
a second gate electrode provided on the second gate insulating film; and
a second channel region located immediately below the second gate insulating film between the second source region and the second drain region and having an identical concentration profile of the impurity of the first conductivity type to the first channel region.

2. The device according to claim 1, further comprising:
a third MOS transistor including:
a third source region and a third drain region of the first conductivity type spaced from each other in the surface of the semiconductor substrate;
a third gate insulating film provided on the surface of the semiconductor substrate between the third source region and the third drain region and having a thicker film thickness than the first gate insulating film;
a third gate electrode provided on the third gate insulating film; and
a third channel region located immediately below the third gate insulating film between the third source region and the third drain region and having an identical concentration profile of the impurity of the first conductivity type to the first channel region.

3. The device according to claim 1, wherein peak value of concentration profile of the impurity of the second conductivity type in the first channel region is higher than peak value of the concentration profile of the impurity of the first conductivity type in the first channel region.

4. The device according to claim 3, wherein concentration of the impurity of the second conductivity type in the first channel region near the first gate insulating film is higher than concentration of the impurity of the first conductivity type.

5. The device according to claim 1, wherein in the first channel region, depth from the surface of the semiconductor substrate to peak position of the concentration profile of the impurity of the first conductivity type is deeper than depth from the surface of the semiconductor substrate to peak position of concentration profile of the impurity of the second conductivity type.

6. The device according to claim 1, wherein in the second MOS transistor, the second channel region near the second gate insulating film is of the first conductivity type.

7. The device according to claim 2, wherein the third channel region of the third MOS transistor further contains the impurity of the second conductivity type.

8. The device according to claim 7, wherein the third channel region near the third gate insulating film is of the second conductivity type.

9. The device according to claim 1, wherein the first drain region and the second drain region have an impurity of the second conductivity type in surface of the semiconductor substrate.

10. A method for manufacturing a nonvolatile memory device including a plurality of kinds of MOS transistors formed in a surface of one semiconductor substrate, the method comprising:
ion-implanting impurity of a second conductivity type into a region constituting a channel of a first MOS transistor by masking a region constituting a channel of a third MOS transistor, which includes a gate insulating film thicker than gate insulating films of the first MOS transistor and a second MOS transistor formed in the semiconductor substrate, and a region constituting a channel of the second MOS transistor;
simultaneously ion-implanting impurity of a first conductivity type into the region constituting the channel of the second MOS transistor and the region constituting the channel of the first MOS transistor; and
ion-implanting the impurity of the first conductivity type into the region constituting the channel of the third MOS transistor simultaneously with the regions constituting the channel of the first MOS transistor and the second MOS transistor.

11. The method according to claim 10, further comprising:
ion-implanting the impurity of the second conductivity type into the entire surface of the semiconductor substrate.

12. The method according to claim 10, wherein dose amount of the impurity of the second conductivity type is larger than dose amount of the impurity of the first conductivity type.

13. The method according to claim 10, wherein the impurity of the first conductivity type is ion-implanted in a dose amount causing a surface of the region constituting the channel of the second MOS transistor to be of the first conductivity type.

14. The method according to claim 13, wherein the impurity of the first conductivity type is ion-implanted in a dose amount causing a surface neighborhood of the region constituting the channel of the third MOS transistor to be of the first conductivity type.

15. The method according to claim 10, wherein a acceleration energy for the ion-implanting impurity of the first conductivity type is higher than that of the ion-implanting impurity of the second conductivity type.
